(19) United States
(12) Patent Application Publication
(10) Pub. No.: US 2009/0033582 A1
(43) Pub. Date: Feb. 5, 2009

(54) RFID tags and antennas and methods of their manufacture

(76) Inventors: Gary P. Blenkhorn, Cape Elizabeth, ME (US); Craig R. Libby, Gorham, ME (US); James C. Baird, Old Orchard Beach, ME (US)

Correspondence Address: FISH & RICHARDSON PC, P.O. BOX 1022, MINNEAPOLIS, MN, 55440-1022, US

(21) Appl. No.: 11/444,711

(22) Filed: Jun. 1, 2006

(51) Int. Cl. H01Q 21/00; H01P 11/00; H01L 21/58; H01Q 1/00

(52) U.S. Cl. 343/893; 29/600; 438/110; 343/700 MS; 257/E21.505

(57) ABSTRACT

Methods are disclosed for manufacturing RFID tags and antennas for RFID tags. The methods described herein facilitate registration of the chip of the RFID tag with its antenna during chip placement. RFID tags and antennas are also disclosed.

### TECHNICAL FIELD

This invention relates to RFID tags (radio frequency identification transponders), antennas for use in RFID tags, and methods of manufacturing such tags and antennas.

### BACKGROUND

Radio Frequency Identification (RFID) is an electronic identification method, which relies on storing and remotely retrieving data using devices called RFID tags or transponders. An RFID tag can be attached to or incorporated into a product, animal, or person. RFID tags contain silicon chips and antennas to enable them to receive and respond to radio-frequency queries from an RFID transceiver or reader. RFID tags listen for a radio signal sent by the RFID reader. When an RFID tag receives a query, it responds by transmitting its unique ID code and other data back to the reader.

During manufacturing of an RFID tag, the chip is placed on and adhered to the antenna. Orientation of the chip relative to the antenna must be very precise in order for proper electrical contact to be made between chip and antenna. Chips used in RFID tags are very small, e.g., on the order of 0.3 mm or less across, complicating registration issues. In one approach to RFID manufacture, antennas are printed on a web, holes are punched along the margins of the web after printing, and a cog drive is used to engage the holes and thereby advance the web during chip placement.

### SUMMARY

The inventors have discovered new processes by which RFID tags can be manufactured at high speed, with relatively few rejects. The processes disclosed herein also allow chips to be registered very precisely with the antennas on which they are to be mounted.

In one aspect, the invention features a method of forming an RFID tag comprising: (a) transferring a first curable material from an engraved roll to a web to form registration elements on the web; (b) forming a plurality of antennas on the web by a process comprising transferring a second curable material to the web using the engraved roll; and (c) placing chips on the antennas to form chip/antenna assemblies, using the registration elements to guide chip placement.

Some implementations may include one or more of the following features. Step (a) comprises configuring the engraved roll so that the second curable material forms a plurality of antenna pre-forms on the web. The method further includes coating a portion of the pre-forms with conductive material. The method further includes filling a recessed portion of the pre-forms with conductive material. The method further includes curing the curable material. The first and second curable materials are the same. The first curable material is electrically non-conductive and the second curable material is electrically conductive. The registration elements are formed simultaneously with the antenna pre-forms. Step (c) includes reading the registration elements with an optical reader. Step (c) includes engaging the registration elements with a mechanical drive. Step (c) includes engaging the registration elements with a stop mechanism. The method further includes trimming off one or more portion(s) of the web containing the registration elements. The method further includes trimming the web to separate the antenna/chip assemblies to form individual RFID tags. The coating step comprises tip printing. Filling the recessed portion comprises scrape coating the pre-form. Tip printing comprises coating a raised area of the pre-form with an adhesive and then applying a conductive material to the adhesive. Filling the recessed portion comprises passing the web over the surface of a roll, with the recessed portions facing away from the roll surface, and flood coating the recessed portions as they pass the roll surface.

In another aspect, the invention features a method of forming an antenna for an RFID tag comprising: (a) transferring a first curable material from an engraved roll to a web to form registration elements on the web; (b) forming a plurality of antennas on the web; and (c) configuring the registration elements to orient the web in two dimensions during chip placement. The invention also features methods of forming RFID tags that include using steps (a)-(c) to form an antenna, and then placing chips on the antennas to form chip/antenna assemblies, using the registration elements to guide chip placement;

In yet another aspect, the invention features a method of forming an RFID tag comprising: (a) transferring a curable material from an engraved roll to a web to form antenna pre-forms on the web; (b) curing the curable material; (c) applying a conductive ink to the pre-forms to form antennas; and (d) placing chips on the antennas to form chip/antenna assemblies. The invention also features a method of forming antennas for use in RFID tags comprising: (a) transferring a curable material from an engraved roll to a web to form antenna pre-forms on the web; (b) curing the curable material; and (c) applying a conductive ink to the pre-forms to form antennas.

Some implementations may include one or more of the following features. Step (c) comprises coating a portion of the pre-forms with conductive material. Step (c) comprises filling a recessed portion of the pre-forms with conductive material. The method further includes trimming the web to separate the antenna/chip assemblies to form individual RFID tags. The coating step comprises tip printing. Filling the recessed portion comprises scrape coating the pre-form. Tip printing comprises coating a raised area of the pre-form with an adhesive and then applying a conductive material to the adhesive. Filling the recessed portion comprises passing the web over the surface of a roll, with the recessed portions facing away from the roll surface, and flood coating the recessed portions as they pass the roll surface.

In a further aspect, the invention features a method of forming an RFID tag comprising: (a) transferring a curable conductive material from an engraved roll to a web to form antennas on the web; (b) curing the curable material; and (d) placing chips on the antennas to form chip/antenna assemblies.

The curable material may be radiation curable, and curing may comprise applying electron beam radiation to the web.

The invention also features antennas for RFID tags, RFID tags that include such antennas, and intermediate products used in the manufacture of RFID tags.

In one aspect, the invention features an antenna for an RFID tag, comprising: (a) a sheet form substrate; (b) a first layer of a non-conductive material, disposed on the substrate and configured to define the shape of the antenna; and (c) a second layer of an electrically conductive material, configured to form the antenna.

Some implementations include one or more of the following features. The first layer of material defines a recess and the electrically conductive material is disposed in the recess. The first layer of material defines a protrusion and the electrically conductive material is disposed on a surface of the protrusion. The non-conductive material comprises a radiation-curable acrylate.

In another aspect, the invention features a product comprising: (a) a sheet form substrate; (b) a plurality of antennas disposed on the substrate; and (c) a plurality of registration elements disposed on the substrate. The positioning of the registration elements relative to the antennas is predetermined, and is identical over the entire surface of the sheet form substrate. The product may be used as an intermediate product in the manufacture of RFID tags. For example, chips may be placed on the antennas to form RFID tags, and the sheet form substrate may be cut to remove and separate the individual RFID tags, with the portion of the web containing the registration elements being discarded.

Some implementations include one or more of the following features. The antennas are formed of a conductive material comprising a radiation cured acrylate binder carrying an electrically conductive filler. The registration elements comprise a radiation cured acrylate. The registration elements comprise protrusions that are raised above the plane of the sheet-form substrate. The registration elements comprise optically readable registration marks. The registration elements are configured to act as a positive stop when engaged with a corresponding stop mechanism of a chip placement machine. The antennas replicate, with substantially 100% fidelity, a predetermined antenna pattern.

The invention also features A method of forming an antenna for an RFID tag, comprising: (a) transferring a curable material from an engraved roll to a first surface of a web to form antenna pre-forms on the first surface, the antenna pre-forms having a recessed area configured to define the shape of the antennas; (b) curing the curable material; and (c) applying a conductive ink to the pre-forms to fill the recesses and thereby form antennas, while supporting a second, opposite surface of the web with a smooth roll. Applying the conductive ink may comprise flood coating the first surface, and the smooth roll may be mounted on a rotogravure press.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagrammatic view of a web including antennas and registration elements for mechanical registration, according to one implementation.

FIG. 1A is a diagrammatic view of a web including antennas and registration elements (registration marks for optical registration), according to one implementation.

FIG. 2 is a diagram showing a chip placement process using a mechanical drive to advance the web using the registration elements shown in FIG. 1.

FIG. 2A is a diagram showing a chip placement process utilizing an optical reader to detect the registration elements shown in FIG. 1A.

FIG. 3 is a diagrammatic top perspective view of a web including antennas and registration elements for mechanical registration, according to another implementation.

FIGS. 4-4A are diagrammatic side views and FIG. 4B is a diagrammatic top view illustrating chip placement using the registration elements shown in FIG. 3.

FIG. 5 is a diagram showing a process for forming antenna pre-forms.

FIGS. 6 and 6A are diagrams showing a process for forming antennas from the pre-forms formed in the process shown in FIG. 5.

FIGS. 7 and 7A are diagrams showing an alternative process for forming antennas from the pre-forms formed in the process shown in FIG. 5.

FIG. 8 is a diagram showing another alternative process for forming antennas from the pre-forms formed in the process shown in FIG. 5.

FIG. 9 is a diagram showing an process for forming antennas in which a conductive coating is applied directly to an engraved roll.

FIG. 9A is a diagrammatic front view of the engraved roll shown in FIG. 9 and coaters for applying coatings to the engraved roll.

Like reference symbols in the various drawings indicate like elements.

### DETAILED DESCRIPTION

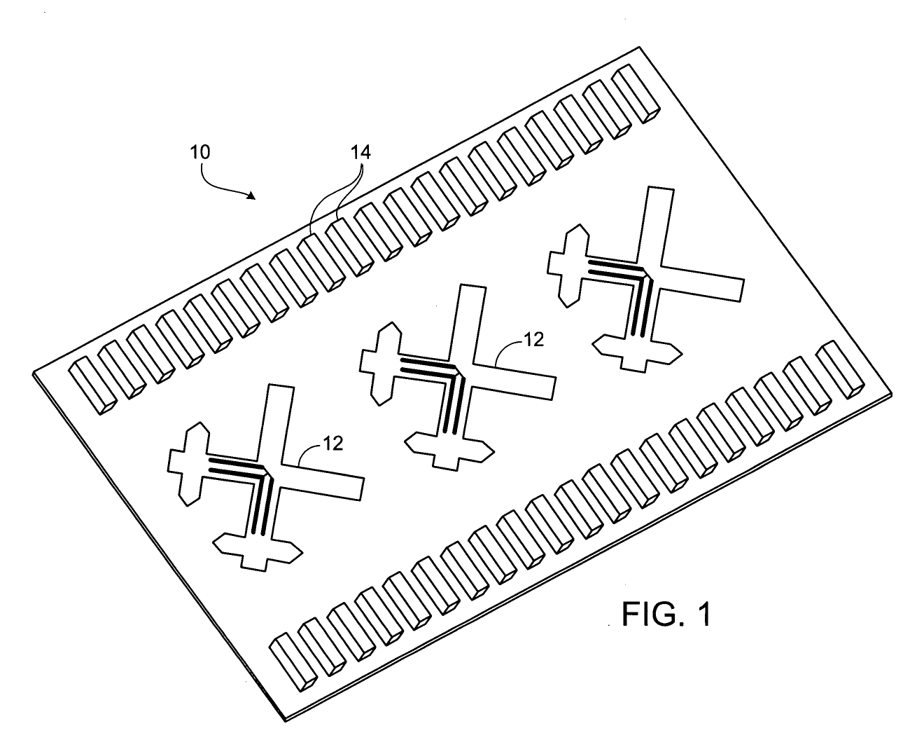

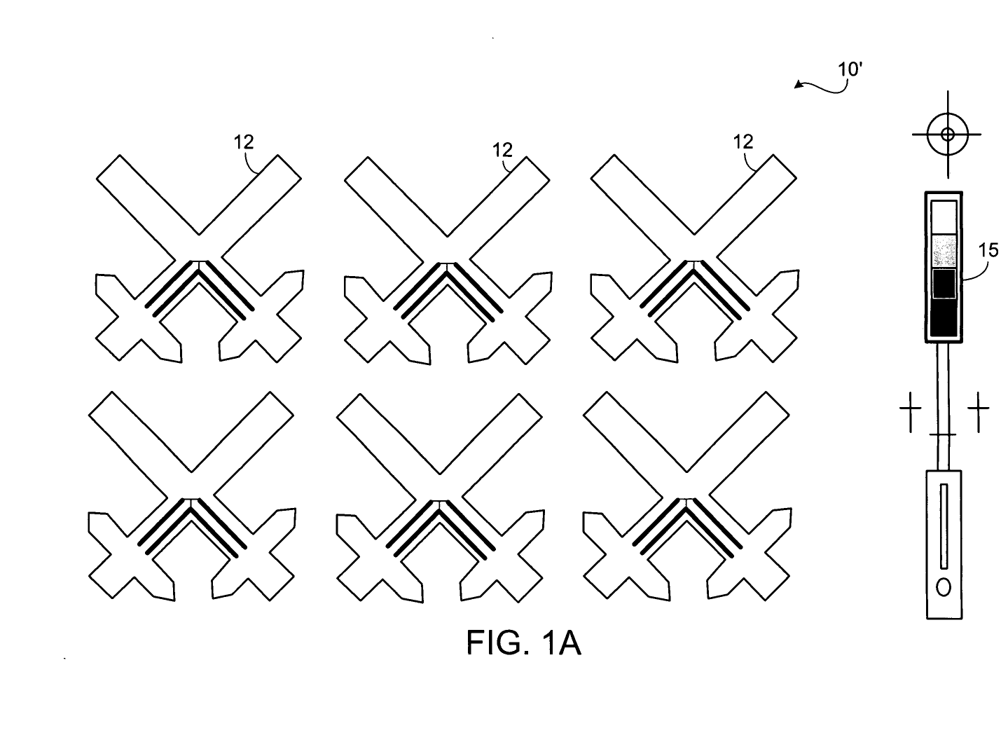

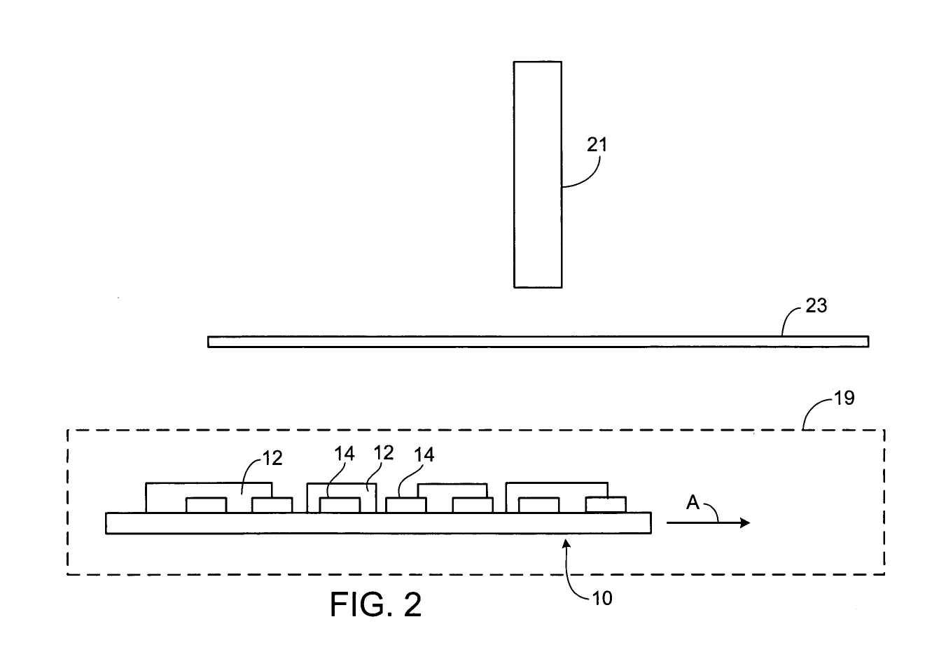

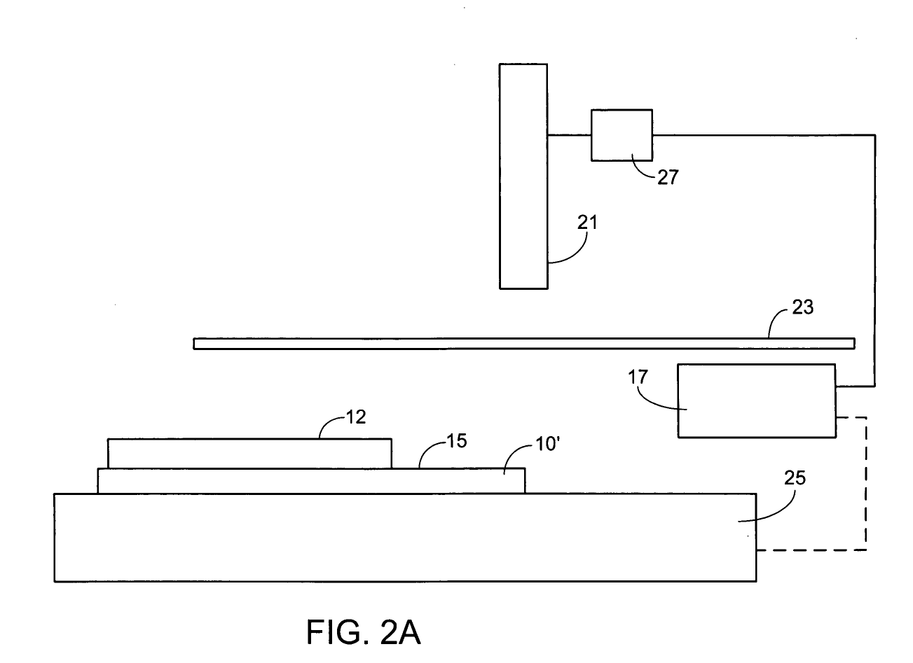

Referring to FIG. 1, in one implementation a web 10 is formed carrying a plurality of antennas 12 and a row of raised registration elements 14 extending along each edge of the web. Referring to FIG. 2, the registration elements 14 may be used by the cogs (not shown) of a mechanical drive 19 to advance the web in direction A. Using the registration elements 14, which are formed simultaneously with the antennas, as will be discussed below, the correct position for placing a chip on a respective antenna can be precisely and accurately determined. As the web 10 is advanced by the engagement of the cogs with the registration elements, the antennas 12 are accurately indexed below a chip placement rod 21 which removes an individual chip (not shown) from a silicon wafer 23 positioned above the web.

In another implementation, shown in FIGS. 1A and 2A, the registration elements comprise registration marks 15 that are in the plane of the web 10′ and are configured to be read by an optical reader 17 (FIG. 2A). As the web 10′ is advanced by a drive device 25, optical reader 17 detects gloss variation or other optical differences between portions of the registration marks. The optical reader communicates this information to a controller 27 for the chip placement rod 21 discussed above.

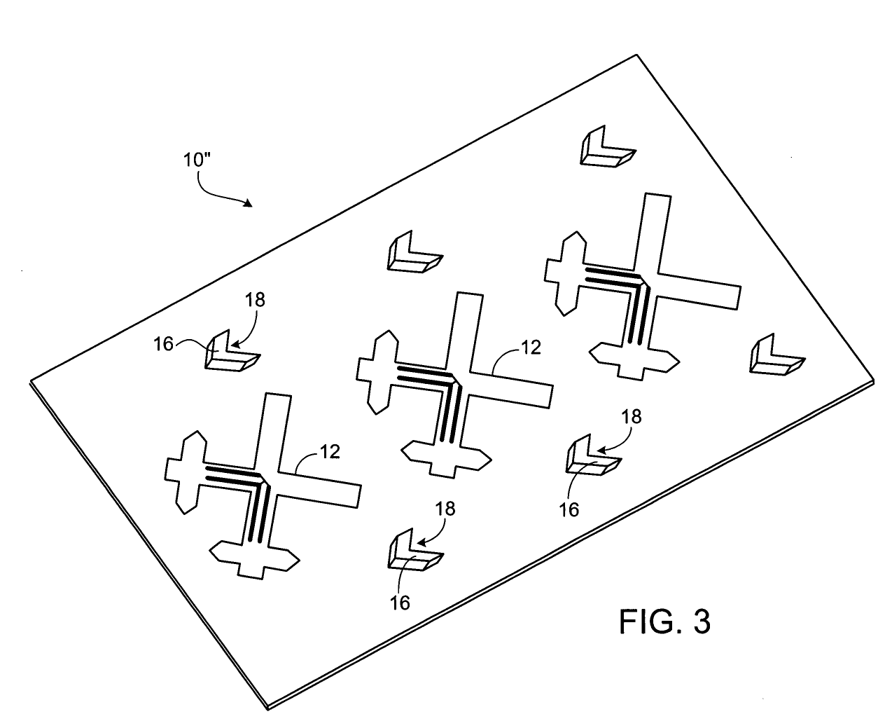

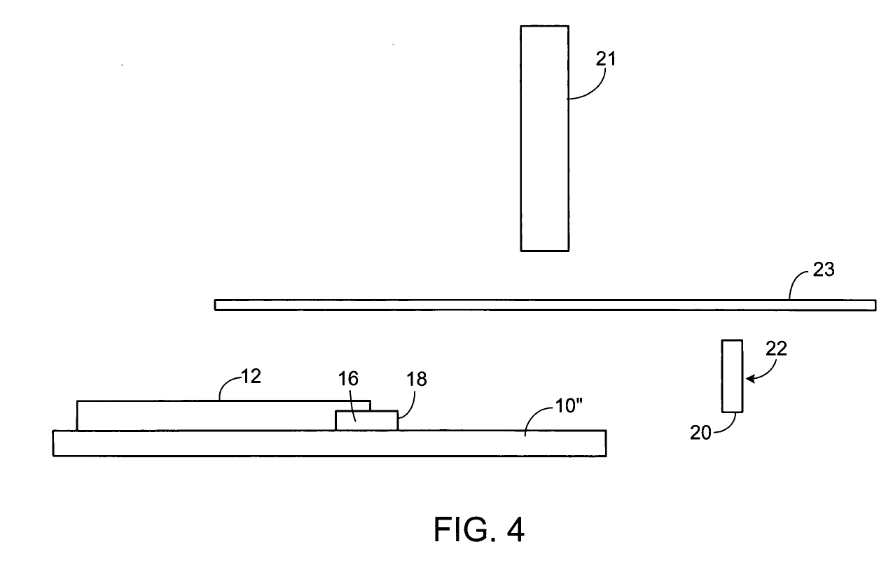

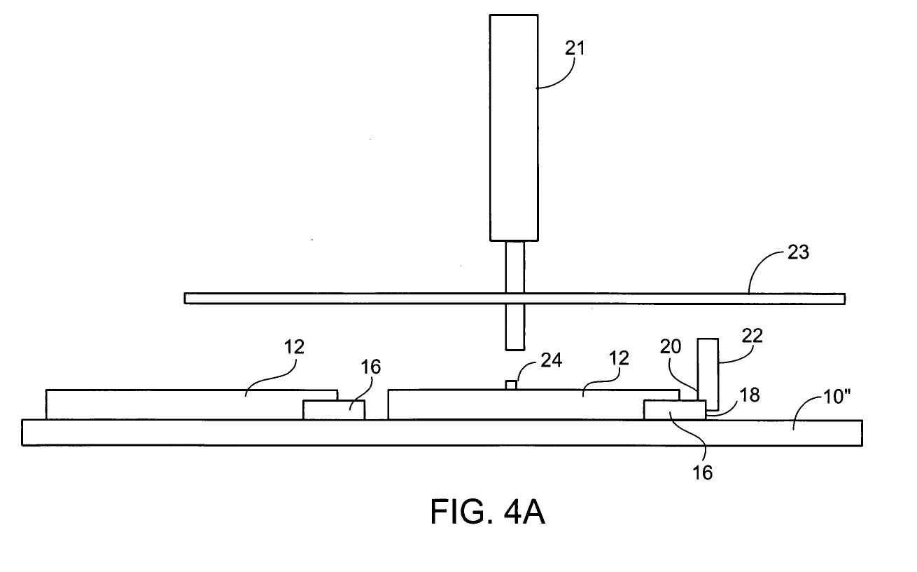

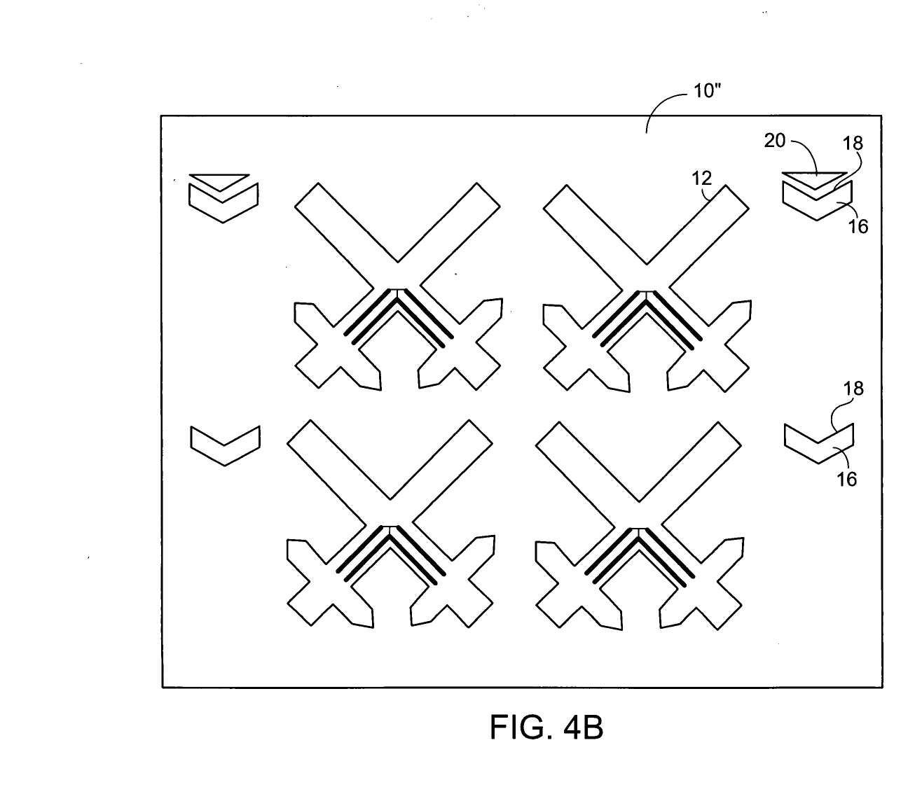

As shown in FIG. 3, in some implementations the registration elements take the form of V-shaped stops 16 that are raised above the plane of the web 10″. Referring to FIGS. 4, 4A and 4B, the inner surface 18 of stops 16 is shaped to engage a correspondingly shaped portion 20 of a stop mechanism 22, stopping the web at the correct position to allow a chip 24 to be accurately registered with an antenna 12 and placed using a chip placement rod 21. The V-shape of the stops and stop mechanism provides good registration in both the x and y directions. The stops may also be used to drive the web, e.g., by engagement with correspondingly shaped cogs of a drive mechanism.

The shape of the registration element in the implementation discussed with respect to FIGS. 3-4B may be any shape that will positively engage a corresponding portion of the stop mechanism and provide registration in the x and y directions, e.g., a half moon shape.

### Forming Antenna Pre-Forms and Registration Elements

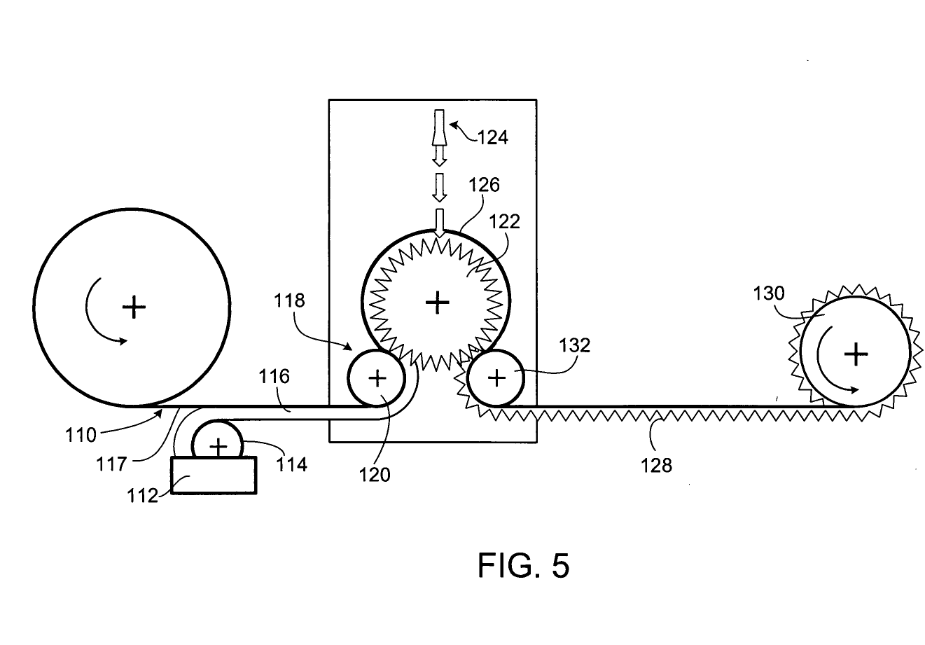

In some implementations, an antenna pre-form is formed by a method that includes coating a curable liquid onto a substrate, imparting a pattern, including both antennas and registration elements, to the coating, e.g., by a mold roll, curing the coating, and stripping the substrate and cured coating from the pattern-imparting surface. Preferably, the entire process is conducted on a continuous web of material which is drawn through a series of processing stations, e.g., as shown diagrammatically in FIG. 5. The process illustrated in FIG. 5 will result in very high fidelity, e.g., substantially 100% fidelity, replication of the desired pattern.

Referring to FIG. 5, in one process a web 110, e.g., a polymeric film, first passes through a coating station 112 at which a coating head 114 applies a wet coating 116 to a surface 117 of the web. Next, the coated web passes through a nip 118 between a backing roll 120 and an engraved roll 122, with the wet coating 116 facing the engraved roll 122. The engraved roll carries a pattern on its surface, the inverse of which is imparted to the wet coating. Nip pressure is generally relatively low (e.g., “kiss” pressure), with the nip pressure being selected based on the viscosity of the coating to prevent the coating from being squeezed off of the web, while still allowing the engraved texture to be imparted to the coating. Typically, higher viscosity coatings and deeper patterns will require relatively higher nip pressures.

After leaving the nip, the coated and patterned web passes through a curing station 124, e.g., an electron beam or UV curing device. The coating is cured while it is still in contact with the surface of the engraved roll. E-beam energy or actinic radiation is generally applied from the back surface 126 of the web and passes through the web and cures the coating 116 to form a hardened, textured coating 128 that is firmly adhered to the web 110. At this point, the web 110 and cured coating 128 may be subjected to one of the further processing steps discussed below, to add a conductive coating to the antenna areas. Alternatively, the web 110 and cured coating 128 may be stripped off the engraved roll at take-off roll 132 and wound up on a take-up roll 130. If UV curing is used, the web should be transparent or translucent if curing is to be performed from the back surface of the web as shown.

The coating 116 may be applied using any suitable method. Suitable techniques include offset gravure, direct gravure, knife over roll, curtain coating, and other printing and coating techniques.

The engraved roll is one example of a replicative surface that may be used to impart the pattern to the wet coating. Other types of pattern-imparting devices may be used. It is generally preferred, however, that the replicative surface be disposed on a rotating endless surface such as a roll, drum, or other cylindrical surface. The coating can be applied directly to the web, before the substrate contacts the roll, as shown in FIG. 5, or alternatively the coating can be applied directly to the roll, in which case the substrate is pressed against the coated roll.

The coating may be cured by thermal curing, electron beam radiation, or UV radiation. Electron beam radiation is preferred in some cases because it can penetrate the thick coatings required for certain desired patterns. Electron beam radiation units are readily available and typically consist of a transformer capable of stepping up line voltage and an electron accelerator. Manufacturers of electron beam radiation units include Energy Sciences, Inc. and PCT Engineered Systems, LLC, Davenport, Iowa. Suitable UV curing devices are commonly available, e.g., from Fusion, Inc., Gaithersburg, Md.

Coating and substrate materials will be discussed below in the “Materials” section.

Forming Antennas from the Antenna Pre-Forms

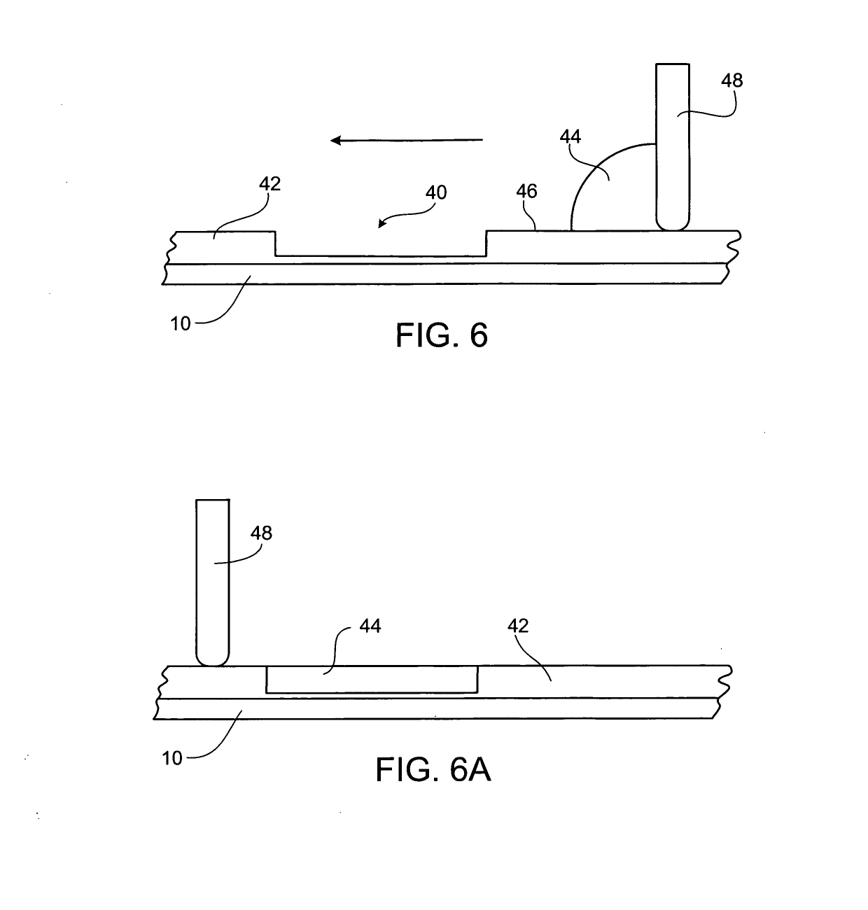

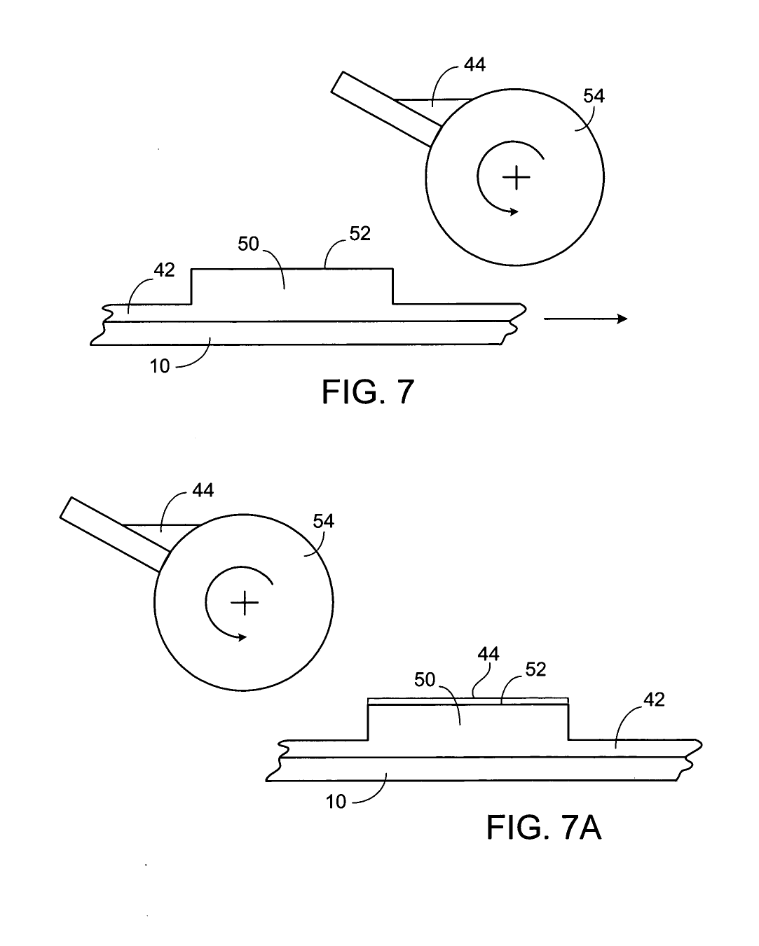

After the antenna pre-forms and registration elements are formed using the process shown in FIG. 5, a conductive ink is applied to the antenna pre-forms to form finished antennas. The conductive ink may be applied, for example, using either of the processes shown in FIGS. 6-6A and 7-7A. The process shown in FIGS. 6-6A, referred to as “scrape coating,” is suitable for use when the pattern applied by the engraved roll during the process of FIG. 6 is the negative of the desired antenna shape (i.e., the pattern on the engraved roll is the positive or “pattern up”). Conversely, the process shown in FIGS. 7-7A, referred to as “tip printing,” is suitable when the pattern applied to the web is the positive of the desired antenna shape.

Referring to FIGS. 6-6A, in the scrape coating process the antenna pre-form is in the form of an antenna-shaped recess 40 in the cured coating 42 on web 10. A conductive ink 44 is applied to the top surface 46 of the cured coating 42, and scraped across the top surface 46 (FIG. 6A) to fill in the recess 40, forming the finished antenna.

Referring to FIGS. 7-7A, in the tip printing process the antenna pre-form is in the form of an antenna-shaped protrusion 50 defined by the cured coating 42. In this case, the conductive ink 44 is applied to the upper surface 52 of protrusion 50, e.g., using a rotating printing roll 54 as shown. Alternatively, an adhesive may be applied to the upper surface 52, and conductive particles or a conductive foil applied to the adhesive.

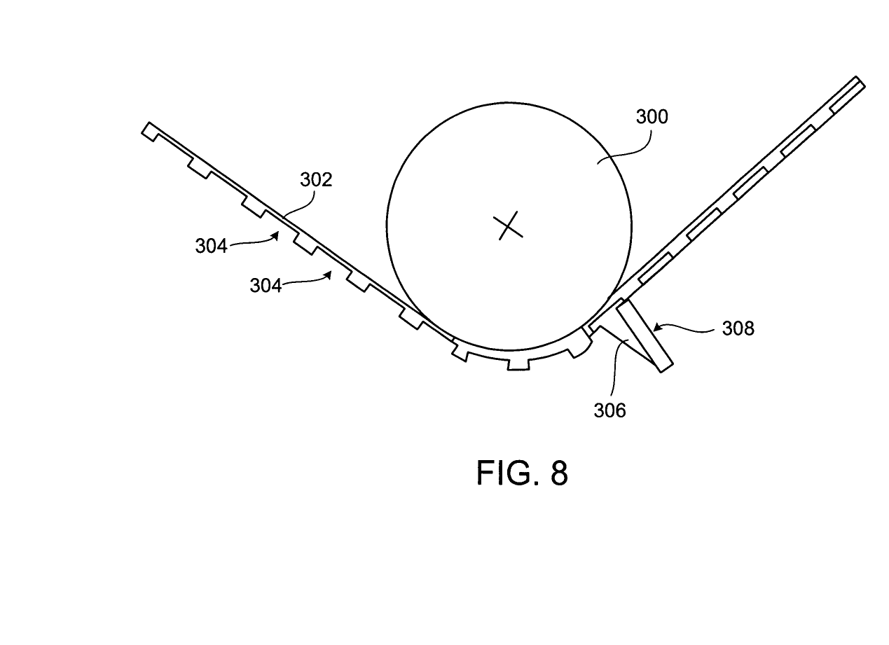

Referring to FIG. 8, in an alternative process a modified rotogravure process is used to transfer conductive ink to the pre-forms. In one implementation of this process, the engraved roll of an existing rotogravure press is replaced by a smooth roll 300. A web 302 carrying recessed antenna pre-forms 304 passes under the surface of the roll 300, and is flood coated with a conductive ink 306 at a coating station 308 which fills the pre-forms with conductive ink.

### Forming Antennas and Registration Elements Using Different Coatings

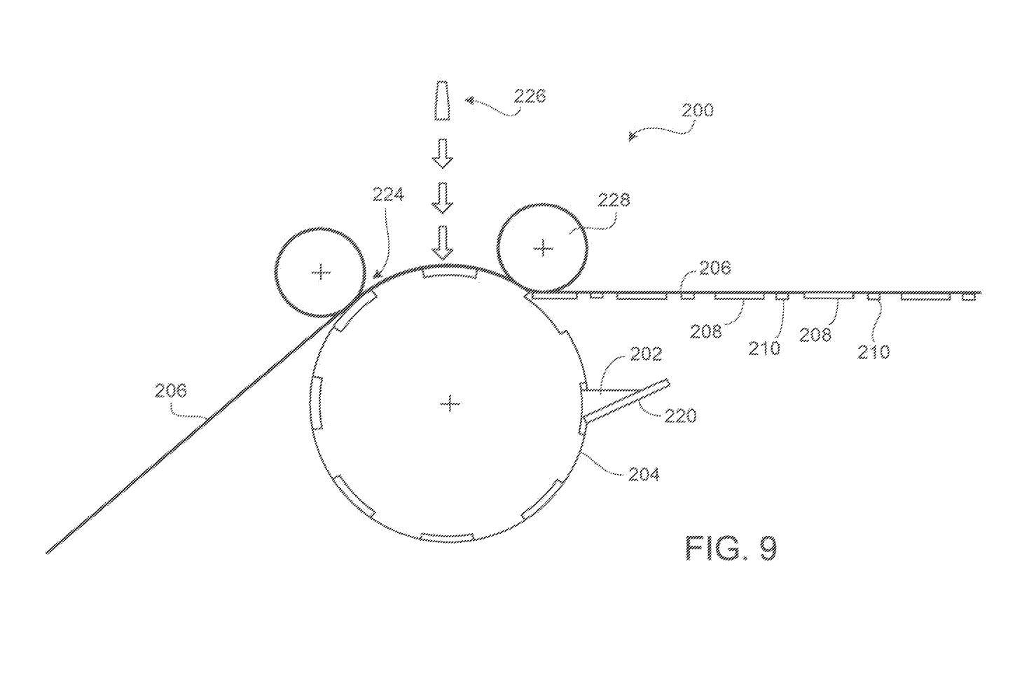

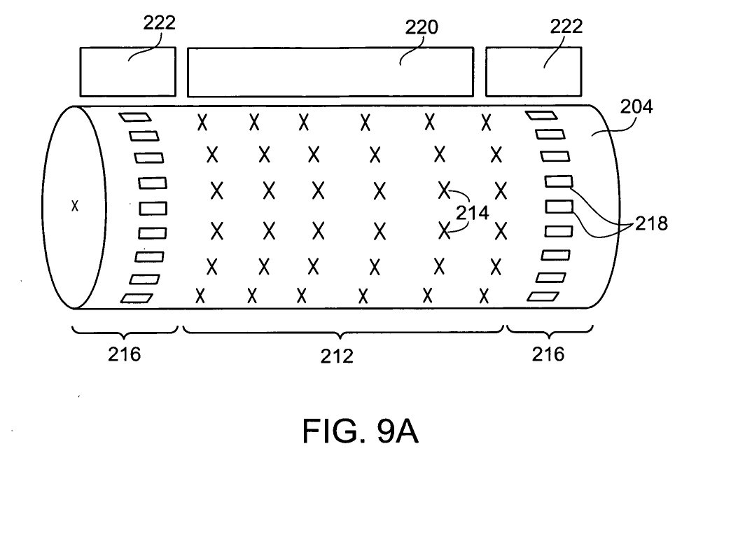

Referring to FIG. 9, in another implementation the antennas and registration elements are formed on a web at a single processing station 200, using different coatings. In this process, pre-forms are not formed, but instead the antennas and registration elements are formed directly on the web.

A curable conductive coating 202 is applied at the center area of an engraved roll 204, and is then transferred to the web 206 to form the antennas 208, and a curable, non-conductive coating (not shown) is applied at each end to form the registration elements 210. For example, referring to FIG. 9A, the engraved roll may include center area 212, engraved with antenna patterns 214, and side areas 216, engraved with registration element patterns 218. Coater 220 delivers the conductive coating 202 to the center area 212, while coaters 222 deliver the non-conductive coating to the side areas 216. Referring again to FIG. 9, the coatings are then transferred to the web 206 at nip 224, cured by an e-beam or UV curing device 226, and the coated web is stripped from the engraved roll at take-off roll 228.

### Materials

The substrate web may be any desired sheet material to which the curable coating will adhere, e.g., a paper or film. Polymeric films to which the coating would not normally adhere can be treated, e.g., by flame treatment, corona discharge, or pre-coating with an adhesion promoter. Suitable substrates include paper, polyester films, and films of cellulose triacetate, biaxially oriented polystyrene and acrylics.

The non-conductive coatings referred to above preferably include an acrylated oligomer, a monofunctional monomer, and a multifunctional monomer for crosslinking. If ultraviolet radiation is used to cure the acrylic functional coating, the coating will also include a photoinitiator as is well known in the art. The conductive coatings may use these ingredients as a binder, to which a silver or other highly electrically conductive filler is added.

Preferred acrylated oligomers include acrylated urethanes, epoxies, polyesters, acrylics and silicones. The oligomer contributes substantially to the final properties of the coating. Practitioners skilled in the art are aware of how to select the appropriate oligomer(s) to achieve the desired final properties. Desired final properties for the release sheet of the invention typically require an oligomer which provides flexibility and durability. A wide range of acrylated oligomers are commercially available from Cytec Surface Specialties Corporation, such as Ebecryl 6700, 4827, 3200, 1701, and 80, and Sartomer Company, Inc., such as CN-120, CN-999 and CN-2920.

Typical monofunctional monomers include acrylic acid, N-vinylpyrrolidone, (ethoxyethoxy)ethyl acrylate, or isodecyl acrylate. Preferably the monofunctional monomer is isodecyl acrylate. The monofunctional monomer acts as a diluent, i.e., lowers the viscosity of the coating, and increases flexibility of the coating. Examples of monofunctional monomers include SR-395 and SR-440, available from Sartomer Company, Inc., and Ebecryl 111 and ODA-N (octyl/decyl acrylate), available from Cytec Surface Specialties Corporation.

Commonly used multifunctional monomers for crosslinking purposes are trimethylolpropane triacrylate (TMPTA), propoxylated glyceryl triacrylate (PGTA), tripropylene glycol diacrylate (TPGDA), and dipropylene glycol diacrylate (DPGDA). Preferably the multifunctional monomer is selected from a group consisting of TMPTA, TPGDA, and mixtures thereof. The preferred multifunctional monomer acts as a crosslinker and provides the cured layer with solvent resistance. Examples of multifunctional monomers include SR-9020, SR-351, SR-9003 and SR-9209, manufactured by Sartomer Company, Inc., and TMPTA-N, OTA-480 and DPGDA, manufactured by Cytec Surface Specialties Corporation.

Preferably, the coating comprises, before curing, 20-50% of the acrylated oligomer, 15-35% of the monofunctional monomer, and 20-50% of the multifunctional monomer. The formulation of the coating will depend on the final targeted viscosity and the desired physical properties of the cured coating. In some implementations, the preferred viscosity is 0.2 to 5 Pascal seconds, more preferably 0.3 to 1 Pascal seconds, measured at room temperature (21-24° C.).

The coating composition may also include other ingredients such as opacifying agents, colorants, slip/spread agents and anti-static or anti-abrasive additives. The opacity of the coating may be varied, for example by the addition of various pigments such as titanium dioxide, barium sulfate and calcium carbonate, addition of hollow or solid glass beads, or addition of an incompatible liquid such as water. The degree of opacity can be adjusted by varying the amount of the additive used.

As mentioned above, a photoinitiator or photoinitiator package may be included if the coating is to be UV cured. A suitable photoinitiator is available from the Sartomer Company under the tradename KTO-46™. The photoinitiator may be included at a level of, for example, 0.5-2%.

### OTHER EMBODIMENTS

A number of embodiments of the invention have been described. Nevertheless, it will be understood that various modifications may be made without departing from the spirit and scope of the invention.

For example, rather than using the processes described above to form the antennas and registration elements, other processes can be used, such as simultaneously screen printing both the registration elements and antennas onto the substrate.

Moreover, while certain registration element shapes have been shown and discussed herein, any desired shape may be used, for example circular, oval, diamond-shaped, etc.

Additionally, the antenna forming techniques described herein can be used to form antennas independently of forming registration elements. For example, the methods of printing conductive inks or coatings can be used to form antennas in applications in which registration elements are not required.

Accordingly, other embodiments are within the scope of the following claims.

What is claimed is:

1. A method of forming an RFID tag comprising:
(a) transferring a first curable material from an engraved roll to a web to form registration elements on the web;
(b) forming a plurality of antennas on the web by a process comprising transferring a second curable material to the web using the engraved roll; and
(c) placing chips on the antennas to form chip/antenna assemblies, using the registration elements to guide chip placement.

2. The method of claim 1 wherein step (a) comprises configuring the engraved roll so that the second curable material forms a plurality of antenna pre-forms on the web.

3. The method of claim 2 further comprising coating a portion of the pre-forms with conductive material.

4. The method of claim 2 further comprising filling a recessed portion of the pre-forms with conductive material.

5. The method of claim 1 further comprising curing the curable material.

6. The method of claim 1 wherein the first and second curable materials are the same.

7. The method of claim 1 wherein the first curable material is electrically non-conductive and the second curable material is electrically conductive.

8. The method of claim 2 wherein the registration elements are formed simultaneously with the antenna pre-forms.

9. The method of claim 1 wherein step (c) includes reading the registration elements with an optical reader.

10. The method of claim 1 wherein step (c) includes engaging the registration elements with a mechanical drive.

11. The method of claim 1 wherein step (c) includes engaging the registration elements with a stop mechanism.

12. The method of claim 1 further comprising (d) trimming off one or more portion(s) of the web containing the registration elements.

13. The method of claim 12 further comprising (e) trimming the web to separate the antenna/chip assemblies to form individual RFID tags.

14. The method of claim 3 wherein coating comprises tip printing.

15. The method of claim 4 wherein filling the recessed portion comprises scrape coating the pre-form.

16. The method of claim 14 wherein tip printing comprises coating a raised area of the pre-form with an adhesive and then applying a conductive material to the adhesive.

17. The method of claim 4 wherein filling the recessed portion comprises passing the web over the surface of a roll, with the recessed portions facing away from the roll surface, and flood coating the recessed portions as they pass the roll surface.

18. A method of forming antennas for use in RFID tags comprising:
(a) transferring a first curable material from an engraved roll to a web to form registration elements on the web;
(b) forming a plurality of antennas on the web; and
(c) configuring the registration elements to orient the web in two dimensions during subsequent placement of chips on the antennas.

19. The method of claim 18 wherein the registration elements are generally V-shaped.

20. A method of forming antennas for use in RFID tags comprising:
(a) transferring a curable material from an engraved roll to a web to form antenna pre-forms on the web;
(b) curing the curable material; and
(c) applying a conductive ink to the pre-forms to form antennas.

21. The method of claim 20 wherein step (c) comprises coating a portion of the pre-forms with conductive material.

22. The method of claim 20 wherein step (c) comprises filling a recessed portion of the pre-forms with conductive material.

23. The method of claim 21 wherein coating comprises tip printing.

24. The method of claim 23 wherein filling the recessed portion comprises scrape coating the pre-form.

25. The method of claim 23 wherein tip printing comprises coating a raised area of the pre-form with an adhesive and then applying a conductive material to the adhesive.

26. The method of claim 23 wherein filling the recessed portion comprises passing the web over the surface of a roll, with the recessed portions facing away from the roll surface, and flood coating the recessed portions as they pass the roll surface.

27. A method of forming RFID tags comprising:
(a) transferring a curable material from an engraved roll to a web to form antenna pre-forms on the web;
(b) curing the curable material;
(c) applying a conductive ink to the pre-forms to form antennas;
(d) applying chips to the antennas to form chip/antenna assemblies; and
(e) trimming the web to separate the antenna/chip assemblies to form individual RFID tags.

28. A method of forming an RFID tag comprising:
(a) transferring a curable conductive material from an engraved roll to a web to form antennas on the web;
(b) curing the curable material; and
(d) placing chips on the antennas to form chip/antenna assemblies.

29. The method of claim 28 wherein curing comprises applying electron beam radiation to the web.

30. An antenna for an RFID tag, comprising:
a sheet form substrate;
a first layer of a non-conductive material, disposed on the substrate and configured to define the shape of the antenna; and
a second layer of an electrically conductive material, configured to form the antenna.

31. The antenna of claim 30 wherein the first layer of material defines a recess and the electrically conductive material is disposed in the recess.

32. The antenna of claim 30 wherein the first layer of material defines a protrusion and the electrically conductive material is disposed on a surface of the protrusion.

33. The antenna of claim 30 wherein the non-conductive material comprises a radiation-curable acrylate.

34. A product comprising:
a sheet form substrate;
a plurality of antennas disposed on the substrate; and
a plurality of registration elements disposed on the substrate;
the positioning of the registration elements relative to the antennas being predetermined and being identical over the entire surface of the sheet form substrate.

35. The product of claim 34 wherein the antennas are formed of a conductive material comprising a radiation cured acrylate binder carrying an electrically conductive filler.

36. The product of claim 34 wherein the registration elements comprise a radiation cured acrylate.

37. The product of claim 34 wherein the registration elements comprise protrusions that are raised above the plane of the sheet-form substrate.

38. The product of claim 34 wherein the registration elements comprise optically readable registration marks.

39. The product of claim 37 wherein the registration elements are configured to act as a positive stop when engaged with a corresponding stop mechanism of a chip placement machine.

40. The product of claim 34 wherein the antennas replicate, with substantially 100% fidelity, a predetermined antenna pattern.

41. A method of forming an antenna for an RFID tag, comprising:
(a) transferring a curable material from an engraved roll to a first surface of a web to form antenna pre-forms on the first surface, the antenna pre-forms having a recessed area configured to define the shape of the antennas;
(b) curing the curable material;
(c) applying a conductive ink to the pre-forms to fill the recesses and thereby form antennas, while supporting a second, opposite surface of the web with a smooth roll.

42. The method of claim 41 wherein applying an conductive ink comprises flood coating the first surface.

43. The method of claim 41 wherein the smooth roll is mounted on a rotogravure press.

44. A method of forming antennas for use in RFID tags, comprising:
(a) transferring a first curable material from an engraved roll to a web to form registration elements on the web; and
(b) forming a plurality of antennas on the web by a process comprising transferring a second curable material to the web using the engraved roll.
